(19) United States
(12) Patent Application Publication
(10) Pub. No.: US 2006/0103643 A1
(43) Pub. Date: May 18, 2006

(54) Measuring and modeling power consumption in displays

(76) Inventors: Mithran Mathew, Mountain View, CA (US); William Cummings, Millbrae, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/182,424

(22) Filed: Jul. 15, 2005

Related U.S. Application Data
(60) Provisional application No. 60/613,537, filed on Sep. 27, 2004.

(51) Int. Cl. G01R 19/00; G09G 5/00

(52) U.S. Cl. 345/212; 324/76.11; 359/290

(57) ABSTRACT

Methods and systems for determining power consumption in displays are described. In some cases, the power may be determined by determining the capacitance of each pixel in the display, where the capacitance may be different for pixels in bright and dark states and for pixels of different color. Methods and systems are also provided for modeling the power consumed by a display depicting a particular image.

### CROSS-REFERENCE TO RELATED APPLICATIONS

This application claims priority to U.S. Provisional Application No. 60/613,537, filed on Sep. 27, 2004, which is incorporated herein by reference in its entirety.

### BACKGROUND OF THE INVENTION

1. Field of the Invention

The field of the invention relates to microelectromechanical systems (MEMS).

2. Description of the Related Art

Microelectromechanical systems (MEMS) include micro mechanical elements, actuators, and electronics. Micromechanical elements may be created using deposition, etching, and or other micromachining processes that etch away parts of substrates and/or deposited material layers or that add layers to form electrical and electromechanical devices. One type of MEMS device is called an interferometric modulator. As used herein, the term interferometric modulator or interferometric light modulator refers to a device that selectively absorbs and/or reflects light using the principles of optical interference. In certain embodiments, an interferometric modulator may comprise a pair of conductive plates, one or both of which may be transparent and/or reflective in whole or part and capable of relative motion upon application of an appropriate electrical signal. In a particular embodiment, one plate may comprise a stationary layer deposited on a substrate and the other plate may comprise a metallic membrane separated from the stationary layer by an air gap. As described herein in more detail, the position of one plate in relation to another can change the optical interference of light incident on the interferometric modulator. Such devices have a wide range of applications, and it would be beneficial in the art to utilize and/or modify the characteristics of these types of devices so that their features can be exploited in improving existing products and creating new products that have not yet been developed.

### SUMMARY OF THE INVENTION

The system, method, and devices of the invention each have several aspects, no single one of which is solely responsible for its desirable attributes. Without limiting the scope of this invention, its more prominent features will now be discussed briefly. After considering this discussion, and particularly after reading the section entitled “Detailed Description of Certain Embodiments” one will understand how the features of this invention provide advantages over other display devices.

One embodiment disclosed herein includes a method of estimating power consumption by a display, comprising measuring capacitance of one or more pixels in the display and determining power consumed by the one or more pixels based on the measured capacitance.

Another embodiment disclosed herein includes a method of estimating power consumption by a display comprising a plurality of interferometric modulators, the method including determining if one or more of the interferometric modulators are in an actuated state or an unactuated state, applying a voltage stimulus to the one or more interferometric modulators, and measuring current to the one or more interferometric modulators that results from the voltage stimulus.

Another embodiment disclosed herein includes a computer-implemented method of modeling power consumed by a display depicting an image, including providing the image as input and determining power consumed by the display while the image is displayed by modeling each pixel with a capacitor, wherein pixels that are off are assigned a different capacitance than pixels that are on.

Another embodiment disclosed herein includes a system for modeling power consumed by a display depicting an image, including a processor and a computer readable medium coupled to the processor and comprising instructions for modeling power consumed by a display by modeling pixels in the display with capacitors, wherein pixels that are off are assigned a different capacitance than pixels that are on.

Another embodiment disclosed herein includes a system for estimating power consumption by a display, including means for measuring a capacitance of at least one pixel in the display and means for predicting power consumed by the display when an image is displayed using the capacitance.

Another embodiment disclosed herein includes a display manufactured by a process that includes forming a plurality of interferometric modulators on a substrate, forming electrical connections to the interferometric modulators, and connecting one or more of the electrical connections to a current sense circuit.

Another embodiment disclosed herein includes a system for measuring power consumed by a display, including an image driver adapted to drive pixels in the display such that a series of images are displayed by the display, a timer adapted to control the amount of time that each image in the series of images is displayed, a voltage sense circuit adapted to measure the voltages applied to the display during display of each image, a current sense circuit adapted to measure the current flowing to or from the display during display of each image, and a power computation module adapted to determine the power consumed by the display while each image is displayed.

Another embodiment disclosed herein includes a method for measuring power consumed by a display, including displaying a series of images on the display and determining power consumed by the display during display of the series of images.

Another embodiment disclosed herein includes a computer-readable medium storing instructions that when executed perform the method the includes reading an image and determining power consumed by a display while the image is displayed on the display by modeling each pixel in the display with a capacitor, wherein pixels that are off are assigned a different capacitance than pixels that are on.

### BRIEF DESCRIPTION OF THE DRAWINGS

FIG. 1 is an isometric view depicting a portion of one embodiment of an interferometric modulator display in which a movable reflective layer of a first interferometric modulator is in a relaxed position and a movable reflective layer of a second interferometric modulator is in an actuated position.

FIG. 2 is a system block diagram illustrating one embodiment of an electronic device incorporating a 3×3 interferometric modulator display.

FIG. 3 is a diagram of movable mirror position versus applied voltage for one exemplary embodiment of an interferometric modulator of FIG. 1.

FIG. 4 is an illustration of a set of row and column voltages that may be used to drive an interferometric modulator display.

FIGS. 5A and 5B illustrate one exemplary timing diagram for row and column signals that may be used to write a frame of display data to the 3×3 interferometric modulator display of FIG. 2.

FIGS. 6A and 6B are system block diagrams illustrating an embodiment of a visual display device comprising a plurality of interferometric modulators.

FIG. 7A is a cross section of the device of FIG. 1.

FIG. 7B is a cross section of an alternative embodiment of an interferometric modulator.

FIG. 7C is a cross section of another alternative embodiment of an interferometric modulator.

FIG. 7D is a cross section of yet another alternative embodiment of an interferometric modulator.

FIG. 7E is a cross section of an additional alternative embodiment of an interferometric modulator.

FIG. 8 is a graph showing the current response in an interferometric modulator to a voltage step.

FIG. 9 is a schematic depicting a current sense circuit for measuring power and/or capacitance in a display.

FIG. 10 is a flowchart depicting a method for determining power and/or capacitance in a display.

FIG. 11 is block diagram depicting a system for measuring power consumption by images displayed on a display.

FIG. 12 is a flowchart depicting a method for estimating power consumption in a display and choosing a power mode based on the estimation.

FIG. 13A depicts a 4×4 checkerboard test pattern for use in modeling power consumption during display of the image.

FIG. 13B depicts voltage timing diagrams for generating the pattern in FIG. 12A on an interferometric modulator display.

FIG. 14A depicts a 16×16 checkerboard test pattern for use in modeling power consumption during display of the image.

FIG. 14B depicts voltage timing diagrams for generating the pattern in FIG. 13A on an interferometric modulator display.

FIG. 15A depicts the transition between two different images for use in modeling power consumption while generating the new image using a partial frame refresh.

FIG. 15B depicts voltage timing diagrams for generating the new image in FIG. 14A on an interferometric modulator display using a partial frame refresh.

### DETAILED DESCRIPTION OF THE CERTAIN EMBODIMENTS

The following detailed description is directed to certain specific embodiments of the invention. However, the invention can be embodied in a multitude of different ways. In this description, reference is made to the drawings wherein like parts are designated with like numerals throughout. As will be apparent from the following description, the embodiments may be implemented in any device that is configured to display an image, whether in motion (e.g., video) or stationary (e.g., still image), and whether textual or pictorial. More particularly, it is contemplated that the embodiments may be implemented in or associated with a variety of electronic devices such as, but not limited to, mobile telephones, wireless devices, personal data assistants (PDAs), hand-held or portable computers, GPS receivers/navigators, cameras, MP3 players, camcorders, game consoles, wrist watches, clocks, calculators, television monitors, flat panel displays, computer monitors, auto displays (e.g., odometer display, etc.), cockpit controls and/or displays, display of camera views (e.g., display of a rear view camera in a vehicle), electronic photographs, electronic billboards or signs, projectors, architectural structures, packaging, and aesthetic structures (e.g., display of images on a piece of jewelry). MEMS devices of similar structure to those described herein can also be used in non-display applications such as in electronic switching devices.

As use of displays in mobile devices become more widespread and such devices have increasing functionality, it is desirable to have displays that have low power consumption. Furthermore, it is desirable to estimate the power consumed by such displays during display of various images so that the power requirements of the mobile devices can be accurately understood and accommodated. Accordingly, methods are provided for determining the power consumed by a given display, including power consumed by pixels that are on or off and of different colors. A system is provided for accurately measuring the power. Furthermore, methods and systems are provided that model the power consumed by a given image displayed on the display.

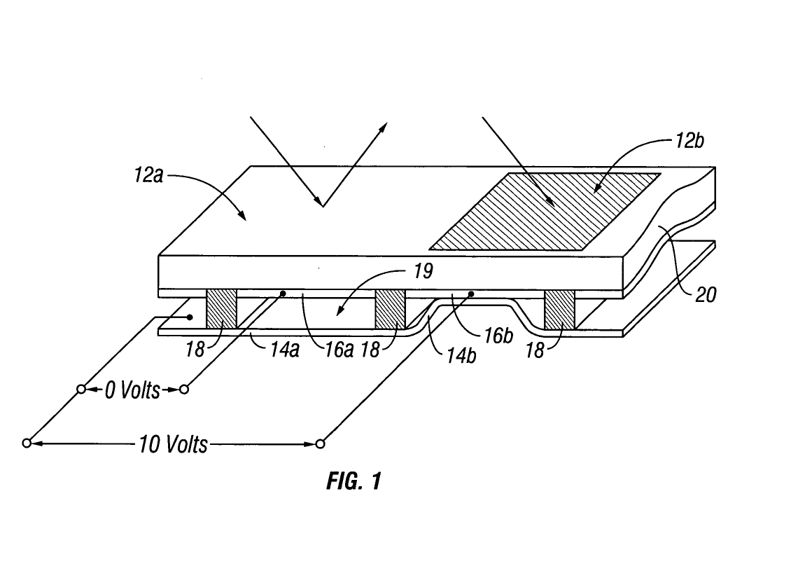

One interferometric modulator display embodiment comprising an interferometric MEMS display element is illustrated in FIG. 1. In these devices, the pixels are in either a bright or dark state. In the bright (“on” or “open”) state, the display element reflects a large portion of incident visible light to a user. When in the dark (“off” or “closed”) state, the display element reflects little incident visible light to the user. Depending on the embodiment, the light reflectance properties of the “on” and “off” states may be reversed. MEMS pixels can be configured to reflect predominantly at selected colors, allowing for a color display in addition to black and white.

FIG. 1 is an isometric view depicting two adjacent pixels in a series of pixels of a visual display, wherein each pixel comprises a MEMS interferometric modulator. In some embodiments, an interferometric modulator display comprises a row/column array of these interferometric modulators. Each interferometric modulator includes a pair of reflective layers positioned at a variable and controllable distance from each other to form a resonant optical cavity with at least one variable dimension. In one embodiment, one of the reflective layers may be moved between two positions. In the first position, referred to herein as the relaxed position, the movable reflective layer is positioned at a relatively large distance from a fixed partially reflective layer. In the second position, referred to herein as the actuated position, the movable reflective layer is positioned more closely adjacent to the partially reflective layer. Incident light that reflects from the two layers interferes constructively or destructively depending on the position of the movable reflective layer, producing either an overall reflective or non-reflective state for each pixel.

The depicted portion of the pixel array in FIG. 1 includes two adjacent interferometric modulators 12a and 12b. In the interferometric modulator 12a on the left, a movable reflective layer 14a is illustrated in a relaxed position at a predetermined distance from an optical stack 16a, which includes a partially reflective layer. In the interferometric modulator 12b on the right, the movable reflective layer 14b is illustrated in an actuated position adjacent to the optical stack 16b.

The optical stacks 16a and 16b (collectively referred to as optical stack 16), as referenced herein, typically comprise of several fused layers, which can include an electrode layer, such as indium tin oxide (ITO), a partially reflective layer, such as chromium, and a transparent dielectric. The optical stack 16 is thus electrically conductive, partially transparent and partially reflective, and may be fabricated, for example, by depositing one or more of the above layers onto a transparent substrate 20. In some embodiments, the layers are patterned into parallel strips, and may form row electrodes in a display device as described further below. The movable reflective layers 14a, 14b may be formed as a series of parallel strips of a deposited metal layer or layers (orthogonal to the row electrodes of 16a, 16b) deposited on top of posts 18 and an intervening sacrificial material deposited between the posts 18. When the sacrificial material is etched away, the movable reflective layers 14a, 14b are separated from the optical stacks 16a, 16b by a defined gap 19. A highly conductive and reflective material such as aluminum may be used for the reflective layers 14, and these strips may form column electrodes in a display device.

With no applied voltage, the cavity 19 remains between the movable reflective layer 14a and optical stack 16a, with the movable reflective layer 14a in a mechanically relaxed state, as illustrated by the pixel 12a in FIG. 1. However, when a potential difference is applied to a selected row and column, the capacitor formed at the intersection of the row and column electrodes at the corresponding pixel becomes charged, and electrostatic forces pull the electrodes together. If the voltage is high enough, the movable reflective layer 14 is deformed and is forced against the optical stack 16. A dielectric layer (not illustrated in this Figure) within the optical stack 16 may prevent shorting and control the separation distance between layers 14 and 16, as illustrated by pixel 12b on the right in FIG. 1. The behavior is the same regardless of the polarity of the applied potential difference. In this way, row/column actuation that can control the reflective vs. non-reflective pixel states is analogous in many ways to that used in conventional LCD and other display technologies.

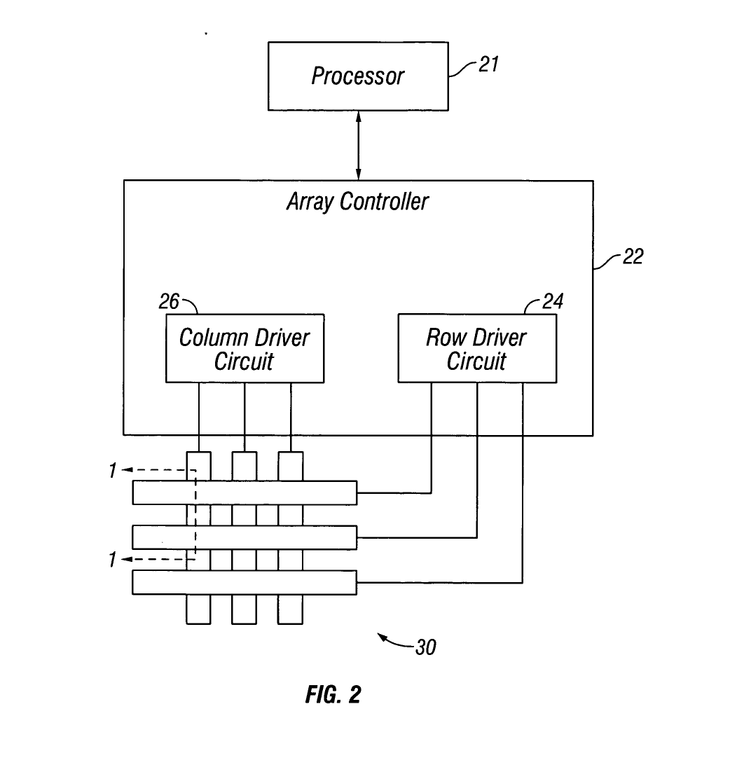

FIGS. 2 through 5 illustrate one exemplary process and system for using an array of interferometric modulators in a display application.

FIG. 2 is a system block diagram illustrating one embodiment of an electronic device that may incorporate aspects of the invention. In the exemplary embodiment, the electronic device includes a processor 21 which may be any general purpose single- or multi-chip microprocessor such as an ARM, Pentium®, Pentium II®, Pentium III®, Pentium IV®, Pentium® Pro, an 8051, a MIPS®, a Power PC®, an ALPHA®, or any special purpose microprocessor such as a digital signal processor, microcontroller, or a programmable gate array. As is conventional in the art, the processor 21 may be configured to execute one or more software modules. In addition to executing an operating system, the processor may be configured to execute one or more software applications, including a web browser, a telephone application, an email program, or any other software application.

In one embodiment, the processor 21 is also configured to communicate with an array driver 22. In one embodiment, the array driver 22 includes a row driver circuit 24 and a column driver circuit 26 that provide signals to a panel or display array (display) 30. The cross section of the array illustrated in FIG. 1 is shown by the lines 1-1 in FIG. 2. For MEMS interferometric modulators, the row/column actuation protocol may take advantage of a hysteresis property of these devices illustrated in FIG. 3. It may require, for example, a 10 volt potential difference to cause a movable layer to deform from the relaxed state to the actuated state. However, when the voltage is reduced from that value, the movable layer maintains its state as the voltage drops back below 10 volts. In the exemplary embodiment of FIG. 3, the movable layer does not relax completely until the voltage drops below 2 volts. There is thus a range of voltage, about 3 to 7 V in the example illustrated in FIG. 3, where there exists a window of applied voltage within which the device is stable in either the relaxed or actuated state. This is referred to herein as the “hysteresis window” or “stability window.” For a display array having the hysteresis characteristics of FIG. 3, the row/column actuation protocol can be designed such that during row strobing, pixels in the strobed row that are to be actuated are exposed to a voltage difference of about 10 volts, and pixels that are to be relaxed are exposed to a voltage difference of close to zero volts. After the strobe, the pixels are exposed to a steady state voltage difference of about 5 volts such that they remain in whatever state the row strobe put them in. After being written, each pixel sees a potential difference within the “stability window” of 3-7 volts in this example. This feature makes the pixel design illustrated in FIG. 1 stable under the same applied voltage conditions in either an actuated or relaxed pre-existing state. Since each pixel of the interferometric modulator, whether in the actuated or relaxed state, is essentially a capacitor formed by the fixed and moving reflective layers, this stable state can be held at a voltage within the hysteresis window with almost no power dissipation. Essentially no current flows into the pixel if the applied potential is fixed.

In typical applications, a display frame may be created by asserting the set of column electrodes in accordance with the desired set of actuated pixels in the first row. A row pulse is then applied to the row 1 electrode, actuating the pixels corresponding to the asserted column lines. The asserted set of column electrodes is then changed to correspond to the desired set of actuated pixels in the second row. A pulse is then applied to the row 2 electrode, actuating the appropriate pixels in row 2 in accordance with the asserted column electrodes. The row 1 pixels are unaffected by the row 2 pulse, and remain in the state they were set to during the row 1 pulse. This may be repeated for the entire series of rows in a sequential fashion to produce the frame. Generally, the frames are refreshed and/or updated with new display data by continually repeating this process at some desired number of frames per second. A wide variety of protocols for driving row and column electrodes of pixel arrays to produce display frames are also well known and may be used in conjunction with the present invention.

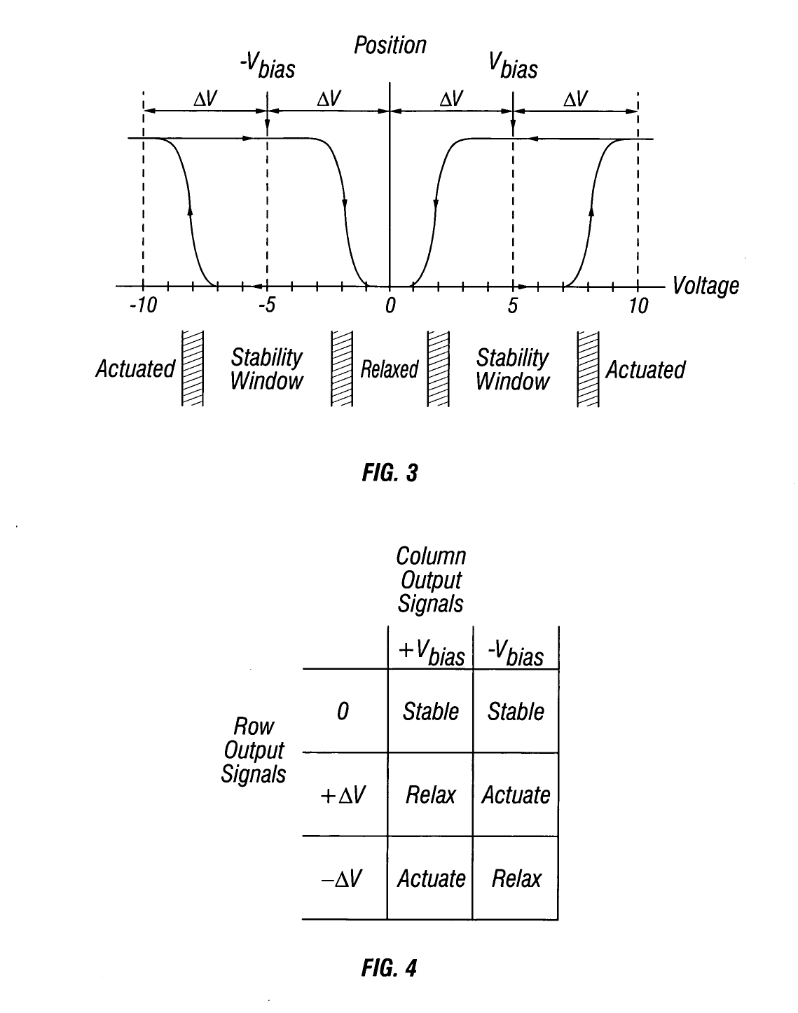

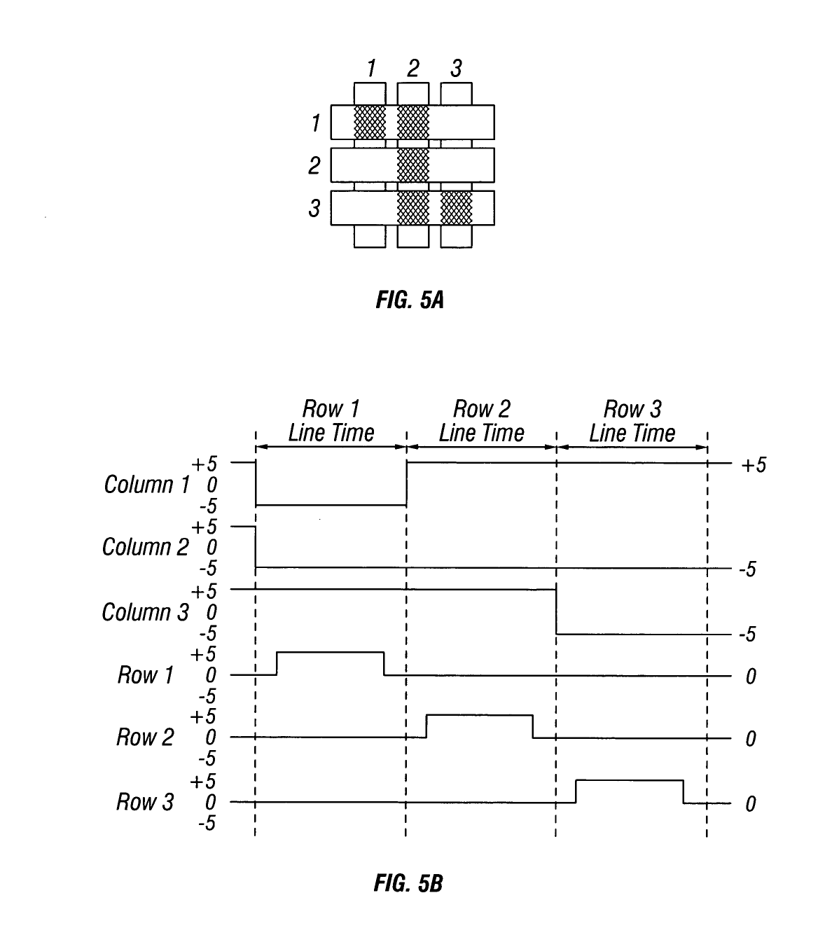

FIGS. 4 and 5 illustrate one possible actuation protocol for creating a display frame on the 3×3 array of FIG. 2. FIG. 4 illustrates a possible set of column and row voltage levels that may be used for pixels exhibiting the hysteresis curves of FIG. 3. In the FIG. 4 embodiment, actuating a pixel involves setting the appropriate column to −V_{bias}, and the appropriate row to +ΔV, which may correspond to −5 volts and +5 volts respectively Relaxing the pixel is accomplished by setting the appropriate column to +V_{bias}, and the appropriate row to the same +ΔV, producing a zero volt potential difference across the pixel. In those rows where the row voltage is held at zero volts, the pixels are stable in whatever state they were originally in, regardless of whether the column is at +V_{bias}, or −V_{bias}. As is also illustrated in FIG. 4, it will be appreciated that voltages of opposite polarity than those described above can be used, e.g., actuating a pixel can involve setting the appropriate column to +V_{bias}, and the appropriate row to −ΔV. In this embodiment, releasing the pixel is accomplished by setting the appropriate column to −V_{bias}, and the appropriate row to the same −ΔV, producing a zero volt potential difference across the pixel.

FIG. 5B is a timing diagram showing a series of row and column signals applied to the 3×3 array of FIG. 2 which will result in the display arrangement illustrated in FIG. 5A, where actuated pixels are non-reflective. Prior to writing the frame illustrated in FIG. 5A, the pixels can be in any state, and in this example, all the rows are at 0 volts, and all the columns are at +5 volts. With these applied voltages, all pixels are stable in their existing actuated or relaxed states.

In the FIG. 5A frame, pixels (1,1), (1,2), (2,2), (3,2) and (3,3) are actuated. To accomplish this, during a “line time” for row 1, columns 1 and 2 are set to −5 volts, and column 3 is set to +5 volts. This does not change the state of any pixels, because all the pixels remain in the 3-7 volt stability window. Row 1 is then strobed with a pulse that goes from 0, up to 5 volts, and back to zero. This actuates the (1,1) and (1,2) pixels and relaxes the (1,3) pixel. No other pixels in the array are affected. To set row 2 as desired, column 2 is set to −5 volts, and columns 1 and 3 are set to +5 volts. The same strobe applied to row 2 will then actuate pixel (2,2) and relax pixels (2,1) and (2,3). Again, no other pixels of the array are affected. Row 3 is similarly set by setting columns 2 and 3 to −5 volts, and column 1 to +5 volts. The row 3 strobe sets the row 3 pixels as shown in FIG. 5A. After writing the frame, the row potentials are zero, and the column potentials can remain at either +5 or −5 volts, and the display is then stable in the arrangement of FIG. 5A. It will be appreciated that the same procedure can be employed for arrays of dozens or hundreds of rows and columns. It will also be appreciated that the timing, sequence, and levels of voltages used to perform row and column actuation can be varied widely within the general principles outlined above, and the above example is exemplary only, and any actuation voltage method can be used with the systems and methods described herein.

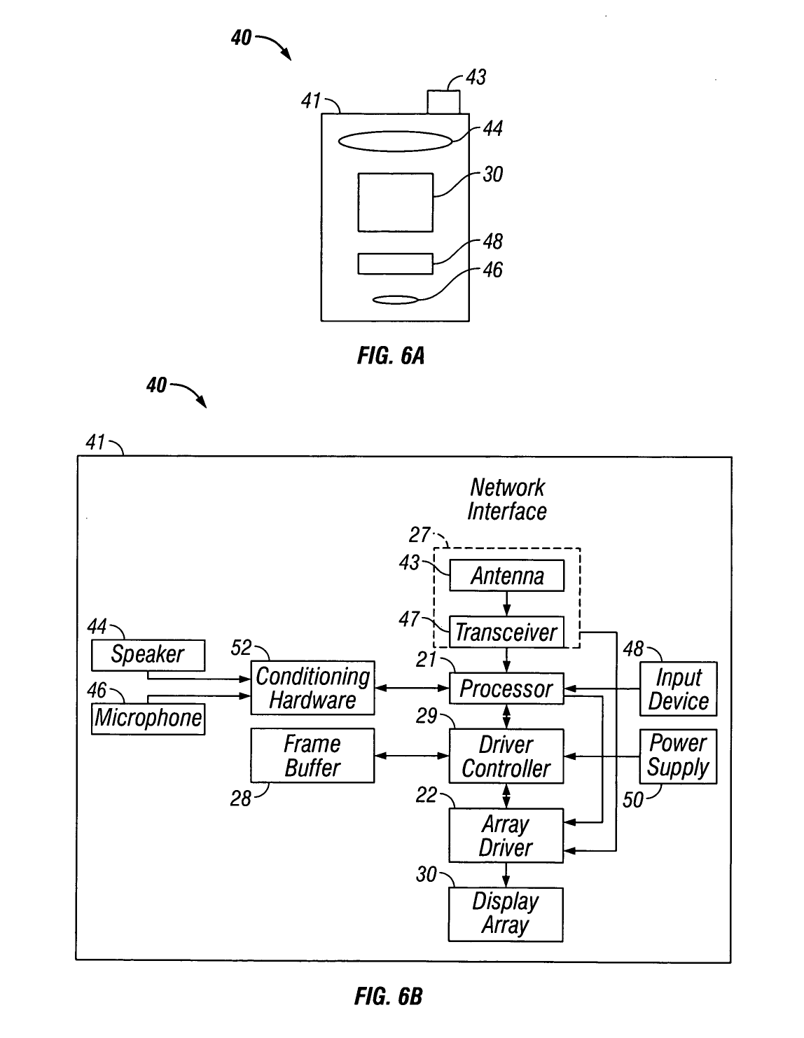

FIGS. 6A and 6B are system block diagrams illustrating an embodiment of a display device 40. The display device 40 can be, for example, a cellular or mobile telephone. However, the same components of display device 40 or slight variations thereof are also illustrative of various types of display devices such as televisions and portable media players.

The display device 40 includes a housing 41, a display 30, an antenna 43, a speaker 45, an input device 48, and a microphone 46. The housing 41 is generally formed from any of a variety of manufacturing processes as are well known to those of skill in the art, including injection molding, and vacuum forming. In addition, the housing 41 may be made from any of a variety of materials, including but not limited to plastic, metal, glass, rubber, and ceramic, or a combination thereof. In one embodiment the housing 41 includes removable portions (not shown) that may be interchanged with other removable portions of different color, or containing different logos, pictures, or symbols.

The display 30 of exemplary display device 40 may be any of a variety of displays, including a bi-stable display, as described herein. In other embodiments, the display 30 includes a flat-panel display, such as plasma, EL, OLED, STN LCD, or TFT LCD as described above, or a non-flat-panel display, such as a CRT or other tube device, as is well known to those of skill in the art. However, for purposes of describing the present embodiment, the display 30 includes an interferometric modulator display, as described herein.

The components of one embodiment of exemplary display device 40 are schematically illustrated in FIG. 6B. The illustrated exemplary display device 40 includes a housing 41 and can include additional components at least partially enclosed therein. For example, in one embodiment, the exemplary display device 40 includes a network interface 27 that includes an antenna 43 which is coupled to a transceiver 47. The transceiver 47 is connected to the processor 21, which is connected to conditioning hardware 52. The conditioning hardware 52 may be configured to condition a signal (e.g. filter a signal). The conditioning hardware 52 is connected to a speaker 45 and a microphone 46. The processor 21 is also connected to an input device 48 and a driver controller 29. The driver controller 29 is coupled to a frame buffer 28 and to the array driver 22, which in turn is coupled to a display array 30. A power supply 50 provides power to all components as required by the particular exemplary display device 40 design.

The network interface 27 includes the antenna 43 and the transceiver 47 so that the exemplary display device 40 can communicate with one ore more devices over a network. In one embodiment the network interface 27 may also have some processing capabilities to relieve requirements of the processor 21. The antenna 43 is any antenna known to those of skill in the art for transmitting and receiving signals. In one embodiment, the antenna transmits and receives RF signals according to the IEEE 802.11 standard, including IEEE 802.11(a), (b), or (g). In another embodiment, the antenna transmits and receives RF signals according to the BLUETOOTH standard. In the case of a cellular telephone, the antenna is designed to receive CDMA, GSM, AMPS or other known signals that are used to communicate within a wireless cell phone network. The transceiver 47 pre-processes the signals received from the antenna 43 so that they may be received by and further manipulated by the processor 21. The transceiver 47 also processes signals received from the processor 21 so that they may be transmitted from the exemplary display device 40 via the antenna 43.

In an alternative embodiment, the transceiver 47 can be replaced by a receiver. In yet another alternative embodiment, network interface 27 can be replaced by an image source, which can store or generate image data to be sent to the processor 21. For example, the image source can be a digital video disc (DVD) or a hard-disc drive that contains image data, or a software module that generates image data.

Processor 21 generally controls the overall operation of the exemplary display device 40. The processor 21 receives data, such as compressed image data from the network interface 27 or an image source, and processes the data into raw image data or into a format that is readily processed into raw image data. The processor 21 then sends the processed data to the driver controller 29 or to frame buffer 28 for storage. Raw data typically refers to the information that identifies the image characteristics at each location within an image. For example, such image characteristics can include color, saturation, and gray-scale level.

In one embodiment, the processor 21 includes a microcontroller, CPU, or logic unit to control operation of the exemplary display device 40. Conditioning hardware 52 generally includes amplifiers and filters for transmitting signals to the speaker 45, and for receiving signals from the microphone 46. Conditioning hardware 52 may be discrete components within the exemplary display device 40, or may be incorporated within the processor 21 or other components.

The driver controller 29 takes the raw image data generated by the processor 21 either directly from the processor 21 or from the frame buffer 28 and reformats the raw image data appropriately for high speed transmission to the array driver 22. Specifically, the driver controller 29 reformats the raw image data into a data flow having a raster-like format, such that it has a time order suitable for scanning across the display array 30. Then the driver controller 29 sends the formatted information to the array driver 22. Although a driver controller 29, such as a LCD controller, is often associated with the system processor 21 as a stand-alone Integrated Circuit (IC), such controllers may be implemented in many ways. They may be embedded in the processor 21 as hardware, embedded in the processor 21 as software, or fully integrated in hardware with the array driver 22.

Typically, the array driver 22 receives the formatted information from the driver controller 29 and reformats the video data into a parallel set of waveforms that are applied many times per second to the hundreds and sometimes thousands of leads coming from the display's x-y matrix of pixels.

In one embodiment, the driver controller 29, array driver 22, and display array 30 are appropriate for any of the types of displays described herein. For example, in one embodiment, driver controller 29 is a conventional display controller or a bi-stable display controller (e.g., an interferometric modulator controller). In another embodiment, array driver 22 is a conventional driver or a bi-stable display driver (e.g., an interferometric modulator display). In one embodiment, a driver controller 29 is integrated with the array driver 22. Such an embodiment is common in highly integrated systems such as cellular phones, watches, and other small area displays. In yet another embodiment, display array 30 is a typical display array or a bi-stable display array (e.g., a display including an array of interferometric modulators).

The input device 48 allows a user to control the operation of the exemplary display device 40. In one embodiment, input device 48 includes a keypad, such as a QWERTY keyboard or a telephone keypad, a button, a switch, a touch-sensitive screen, a pressure- or heat-sensitive membrane. In one embodiment, the microphone 46 is an input device for the exemplary display device 40. When the microphone 46 is used to input data to the device, voice commands may be provided by a user for controlling operations of the exemplary display device 40.

Power supply 50 can include a variety of energy storage devices as are well known in the art. For example, in one embodiment, power supply 50 is a rechargeable battery, such as a nickel-cadmium battery or a lithium ion battery. In another embodiment, power supply 50 is a renewable energy source, a capacitor, or a solar cell, including a plastic solar cell, and solar-cell paint. In another embodiment, power supply 50 is configured to receive power from a wall outlet.

In some implementations control programmability resides, as described above, in a driver controller which can be located in several places in the electronic display system. In some cases control programmability resides in the array driver 22. Those of skill in the art will recognize that the above-described optimization may be implemented in any number of hardware and/or software components and in various configurations.

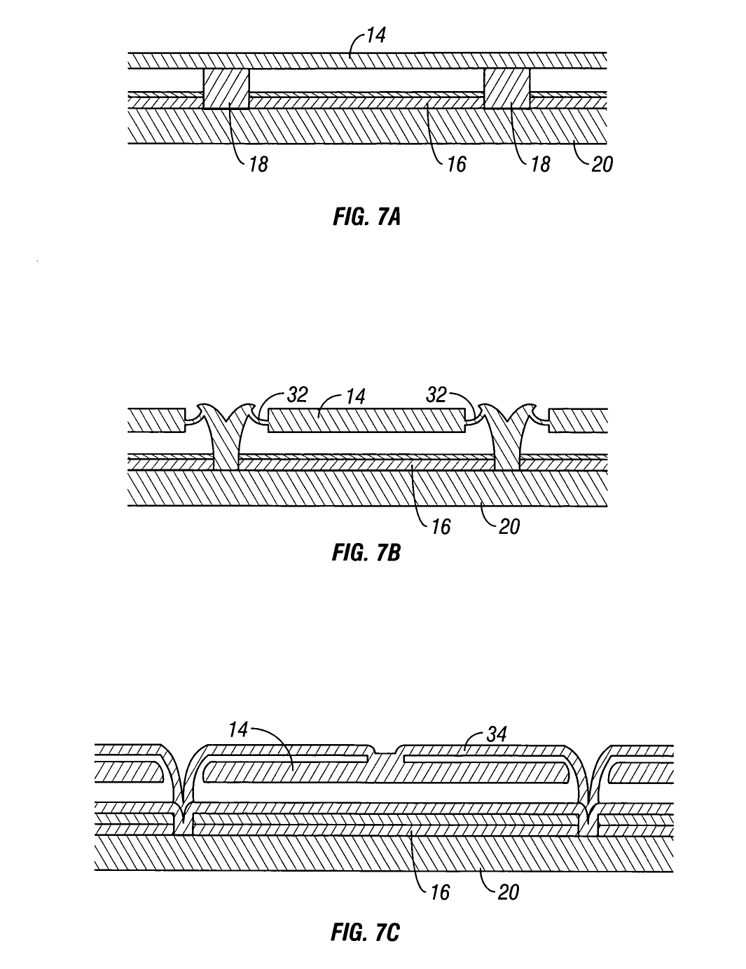

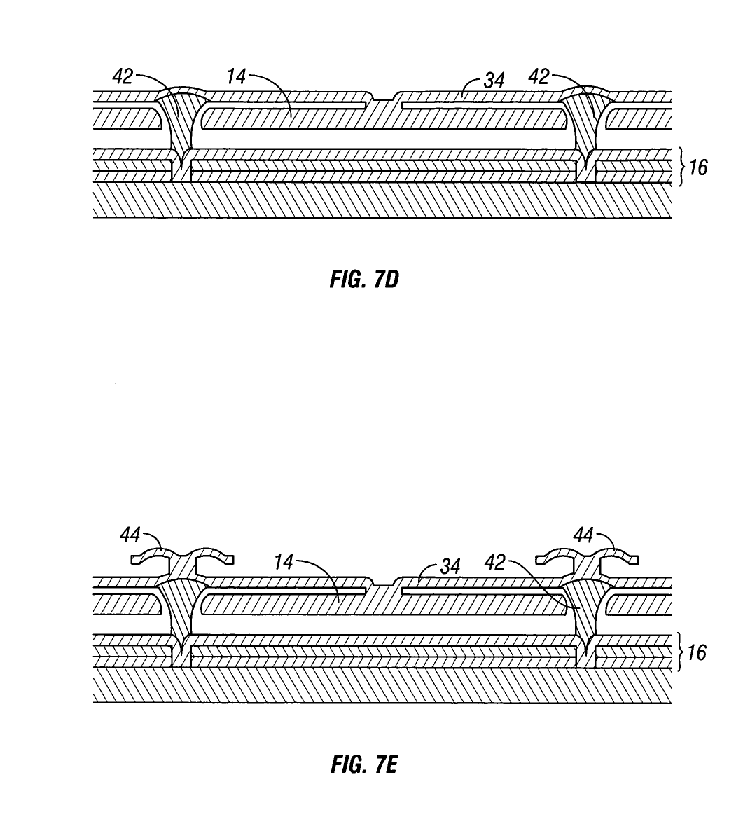

The details of the structure of interferometric modulators that operate in accordance with the principles set forth above may vary widely. For example, FIGS. 7A-7E illustrate five different embodiments of the movable reflective layer 14 and its supporting structures. FIG. 7A is a cross section of the embodiment of FIG. 1, where a strip of metal material 14 is deposited on orthogonally extending supports 18. In FIG. 7B, the moveable reflective layer 14 is attached to supports at the corners only, on tethers 32. In FIG. 7C, the moveable reflective layer 14 is suspended from a deformable layer 34, which may comprise a flexible metal. The deformable layer 34 connects, directly or indirectly, to the substrate 20 around the perimeter of the deformable layer 34. These connections are herein referred to as support posts. The embodiment illustrated in FIG. 7D has support post plugs 42 upon which the deformable layer 34 rests. The movable reflective layer 14 remains suspended over the cavity, as in FIGS. 7A-7C, but the deformable layer 34 does not form the support posts by filling holes between the deformable layer 34 and the optical stack 16. Rather, the support posts are formed of a planarization material, which is used to form support post plugs 42. The embodiment illustrated in FIG. 7E is based on the embodiment shown in FIG. 7D, but may also be adapted to work with any of the embodiments illustrated in FIGS. 7A-7C as well as additional embodiments not shown. In the embodiment shown in FIG. 7E, an extra layer of metal or other conductive material has been used to form a bus structure 44. This allows signal routing along the back of the interferometric modulators, eliminating a number of electrodes that may otherwise have had to be formed on the substrate 20.

In embodiments such as those shown in FIG. 7, the interferometric modulators function as direct-view devices, in which images are viewed from the front side of the transparent substrate 20, the side opposite to that upon which the modulator is arranged. In these embodiments, the reflective layer 14 optically shields some portions of the interferometric modulator on the side of the reflective layer opposite the substrate 20, including the deformable layer 34 and the bus structure 44. This allows the shielded areas to be configured and operated upon without negatively affecting the image quality. This separable modulator architecture allows the structural design and materials used for the electromechanical aspects and the optical aspects of the modulator to be selected and to function independently of each other. Moreover, the embodiments shown in FIGS. 7C-7E have additional benefits deriving from the decoupling of the optical properties of the reflective layer 14 from its mechanical properties, which are carried out by the deformable layer 34. This allows the structural design and materials used for the reflective layer 14 to be optimized with respect to the optical properties, and the structural design and materials used for the deformable layer 34 to be optimized with respect to desired mechanical properties.

Power Consumption in Interferometric Modulator Displays

With reference to FIG. 1, it will be appreciated that an interferometric modulator has structural characteristics that make it behave electrically similar to a capacitor. The interferometric modulators of FIG. 1 both include parallel conductive plates separated by different gaps. In general, two parallel conductive plates can form a capacitor with the capacitance given by:

$$C = \frac{ɛ A}{D}$$

where C is the capacitance, ε is the permittivity of the material between the two conductive plates, A is the area of the plates, and D is the distance between the plates. In the unactuated interferometric modulators, the conductive mirror 14a is separated from conductor 16a by a gap that is larger than the gap between conductive mirror 14b and conductor 16b in actuated interferometric modulators. Accordingly, the capacitance of actuated interferometric modulators is larger than unactuated interferometric modulators.

In one embodiment, a significant source of power consumption in an interferometric modulator display is from capacitive charging of the actuated and unactuated interferometric modulators. Because the capacitance of actuated and unactuated interferometric modulators is different, power consumption in an interferometric modulator will vary depending upon the image displayed in a given frame. As discussed further below, the frame content difference in power consumption is due both to the numbers of actuated and unactuated interferometric modulators as well as the location of the respective pixels within the image.

In one embodiment, power consumed by pixels in an on state is determined separately from power consumed by pixels in an off state. In one embodiment, power consumed by on or off pixels is determined by measuring power consumed by a single on or off pixel. In another embodiment, power consumed by an entire row or column of on or off pixels is measured in order to determine the average power consumed by a single on or off pixel. In one embodiment, power consumed by all the pixels in a display being on or off are measured in order to determine the average power consumed by a single on or off pixel. In one embodiment, the power consumed by one or more pixels is measured by applying a voltage step to the pixels and measuring the resulting current. In one embodiment, the resulting current is measured over a period of time. Integrating the current and multiplying by the value of the voltage step will provide the power consumed according to the following:
P=Vₛ∫^{T}₀i(t)dt
where Vₛ is the magnitude of the voltage step (assuming a constant voltage), i(t) is the resulting current as a function of time, and T is the period of time over which the power is determined. In some embodiments of an interferometric modulator display, Vₛ is 2V_{bias}. As described in more detail below, the most significant contribution to power consumption in interferometric modulator displays is voltage switching on the column lines, which typically are transitions from +V_{bias} to −V_{bias} and vice versa. Accordingly, using a test voltage step of 2V_{bias} will provide a measure of the power consumed by pixels exposed to typical voltage switching on the column lines.

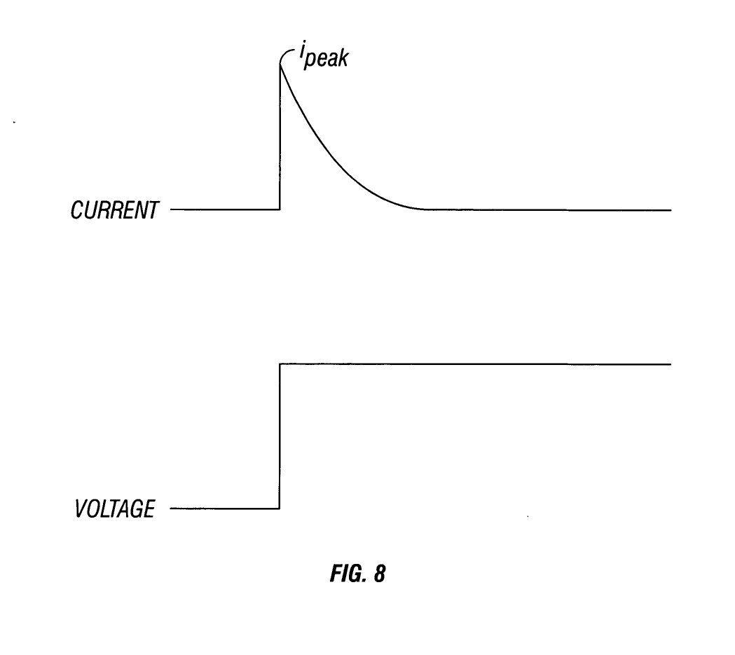

In another embodiment, the pixels are assumed to behave like an ideal capacitor. Accordingly, two or more current values may be obtained at different times and then fit to the expected response for an ideal capacitor to determine the capacitance and/or power consumed by the pixels. For example, in one embodiment, the current peak is measured after application of the voltage step and then a second current value is recorded after an amount of elapsed of time. The current response observed after application of a voltage step is depicted in FIG. 8. In some embodiments, the two or more current measurements are used to determine a relaxation time for the pixels, which can then be used to determine capacitance and/or power. Given the current peak after a voltage step and the relaxation time, the power may be determined from:
P=Vₛiₚₑₐₖ∫^{T}₀e^{-t/τ}dt=Vₛiₚₑₐₖτ(1−e^{-T/τ)}
where Vₛ is the magnitude of the voltage step, iₚₑₐₖ is the value of the peak current after the current step, T is a time period over which the power is desired, and τ is the relaxation time. Those of skill in the art will appreciate that power and capacitance values may be determined by applying any number of voltage or current stimuli and then measuring the resulting current or voltage, respectively.

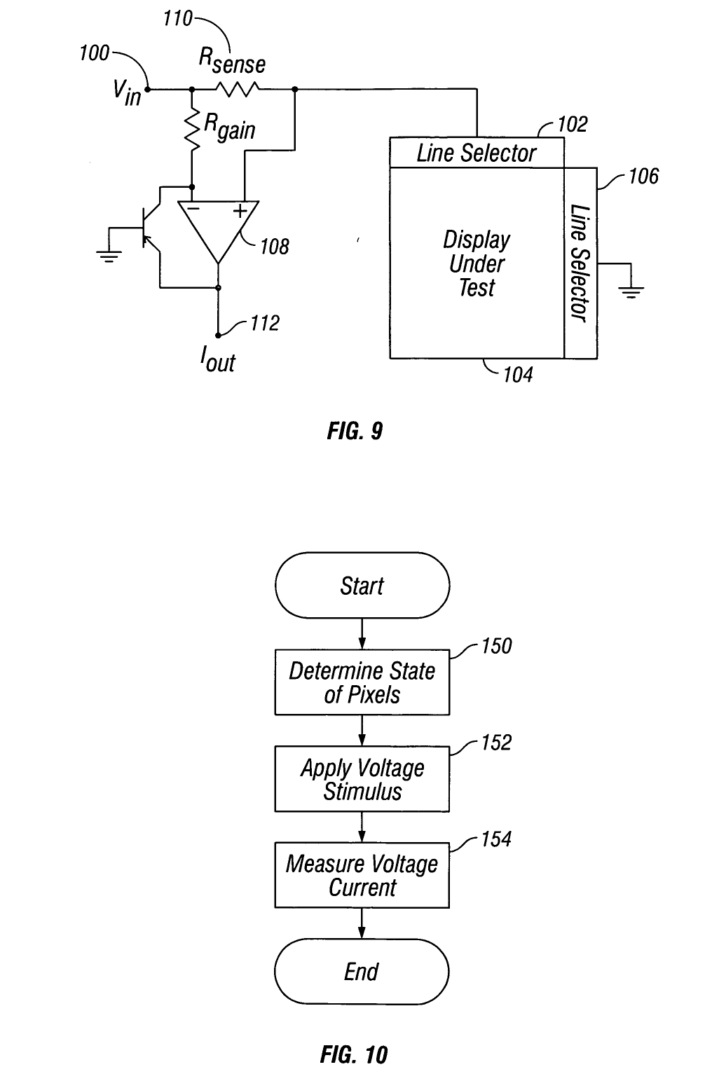

In one embodiment, current resulting from applying a voltage stimulus may be determined using a current sense amplifier. An example of a circuit for implementing a current sense amplifier is depicted in FIG. 9. The voltage stimulus is provided at node 100. The voltage stimulus provides voltage to line selector 102 that is coupled to one or more lines on the display 104 under test. One or more other lines on the display 104 are coupled to a line selector 106, which is connected to ground. In some embodiments, the line selector 102 is coupled to one or more column lines in the display 104 and the line selector 106 is coupled to one or more row lines in the display 104. In one embodiment, the display 104 is a display array 30 such as depicted in FIGS. 5A, 6A and 6B. The line selectors 102 and 106 may provide the ability to selectively couple to one or more columns and rows. Alternatively, the line selectors 102 and 106 may be hard wired to a set one or more columns and rows. In one embodiment, the line selectors 102 and 106 allow the voltage stimulus to be provided to a desired individual pixel, a desired column, a desired row, or groups of columns and/or rows. In one embodiment, line selectors 102 and 106 are coupled to all columns and rows respectively such that the entire display is gang driven (e.g., all pixels are driven with the same voltage stimulus). The current response to the voltage stimulus is detected through the use of the amplifier 108 connected across a sense resistor 110. The current is then provided at output node 112.

In an alternative embodiment, the current sense amplifier may be placed between the line selectors 102 and 106 and the display. In this embodiment, the current sense amplifier may be simultaneously coupled to all rows and/or columns. However, current will only flow through the rows and/or columns that are selected by line selectors 102 and 106. In one embodiment, multiple current sense amplifier circuits are provided between the line selectors 102 and 106 and the display. Thus, for example, a current sense amplifier may be provided for each row and/or column.

In embodiments where the display includes subpixels having different colors, capacitance and/or power values may be determined for the on and off states of each color subpixel. For example, in some interferometric modulator displays, the number of interferometric modulators for each color subpixel will differ from other color subpixels in order to provide a desired color balance. Accordingly, each color subpixel will have different capacitance values from other color subpixels in the same state due to the increase area of the conductive surfaces. Furthermore, the gap in unactuated interferometric modulators will differ for different colors resulting in different capacitance values.

In one embodiment, prior to determining the capacitance and/or power consumption of one or more pixels, the state of the pixels are determined so that it is known what state is being probed. Accordingly, as depicted in the flow chart in FIG. 10, one embodiment for determining power and/or capacitance of one or more pixels includes determining whether the pixels are on or off at block 150, applying a voltage stimulus to the pixels at block 152, and then measuring the resulting current at block 154. Depending on the particular embodiment, steps may be added to those depicted in FIG. 10 or some steps may be removed. In addition, the order of steps may be rearranged depending on the application. In one embodiment, the voltage stimulus is a voltage step. In various embodiments, whether the pixels are on or off is determined by visually observing the pixels, detecting light from the pixels with a photodetector or spectrometer, or measuring the optical state of the pixels. In one embodiment, the pixels include interferometric modulators and determining whether the pixels are on or off is performed by applying a voltage or series of voltages that are known to place the interferometric modulators in either an actuated or unactuated state.

In one embodiment, the systems and methods discussed above are used to test a display wafer prior to packaging into a system to determine whether the wafer is suitable for use as a display or not. If the measured power characteristics are not as desired, the wafer can be discarded prior to incurring the expense of incorporating the wafer into a system. In one embodiment, devices are manufactured on the wafer to facilitate testing. For example, the line selectors 102 and 106 may be manufactured on the display wafer. In one embodiment, the line selectors 102 and 106 include buss bars connecting multiple leads to test pads for contact with testing electronics. In one embodiment, a current sense circuit, such as depicted in FIG. 8, may also be incorporated onto the wafer to facilitate testing.

In another embodiment, the systems and methods described above may be implemented into a display system to test the power consumption of the display while the device is in use. Such an implementation may be used to indicate problems with the display as well as to provide an indication of the power needs of the display to facilitate power distribution within the device.

Determining Power Consumption during Display of Images

In one embodiment, power consumed by images being displayed on a display is determined. In one embodiment, a series of images are displayed on the display. Power consumption may be determined during display of each image. In one embodiment, instantaneous power consumption at any time during display of the image is determined. In another embodiment, power consumed during display of each frame of each image is determined. In another embodiment, average power consumption during display of each image is determined. In another embodiment, average power consumption during display of the entire series of images in determined. In one embodiment, determining power consumption includes measuring current flow to or from the display during display of the images. Any suitable current sense circuit may be used. For example, the current sense amplifier described above may be used. In one embodiment, the voltages applied to the display during display of the images are also measured and the measured voltage and current is used to compute power consumption. Alternatively, the voltages applied to the display may be determined from the voltages applied by an image driver used to drive the display. In one embodiment, the amount of time that each image is displayed during display of the series of images is varied.

The above-described method for determining power consumption is advantageously used to determine power consumption by an interferometric modulator display. As discussed in more detail below, power consumption by an interferometric modulator display is highly image content dependent. Therefore, applying a series of images provides a more accurate estimation of power consumption during use of the display than measuring power consumption during display of a single image.

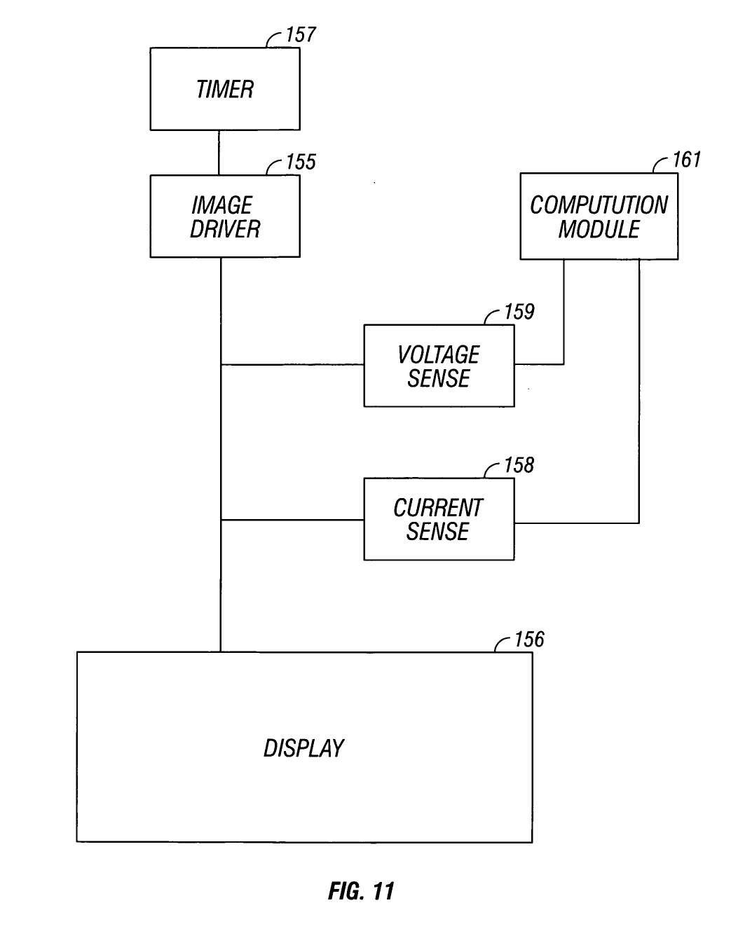

FIG. 11 depicts a system that may be used for measuring power consumption in a display. An image driver 155 may be used for driving an image onto a display 156. The image driver 155 may operate by applying voltages or a series of voltages to rows and/or columns of the display 156 such that pixels in the display 156 are driven to produce a desired image. The image driver 155 may be used to apply a series of images to the display 156. In one embodiment, a timer 157 is provided for controlling the amount of time that each image is displayed on the display 156. In one embodiment, the timer 156 may be incorporated into the image driver 155. A current sense circuit 158 and a voltage sense circuit 159 may be provided to measure the voltages and currents applied to the display 156. Any suitable current sense circuit 158 and voltage sense circuit 159 may be utilized. In some embodiments, the current sense circuit 158 and voltage sense circuit 159 may be used to measure voltage and current applied to each individual column and/or row. In one embodiment, the current sense circuit 158 and voltage sense circuit 159 may be incorporated within the image driver 155. A power computation module 161 may be coupled to the current sense circuit 158 and voltage sense circuit 159 for determining power consumption.

Modeling Power Consumption in Displays

In one embodiment, power consumption in a display is modeled by representing each pixel as a capacitor, where pixels that are on (e.g., unactuated interferometric modulators) and pixels that are off (e.g., actuated interferometric modulators) have different capacitance values. Capacitance values of on and off pixels may be determined as discussed above or by any suitable method known to those of skill in the art. An image containing information of the state of each pixel may then be provided and an estimate of power consumption during display of the image for one or more frames determined based on the capacitance of each pixel and the voltage driving scheme applied to the pixels.

As discussed above with reference to FIGS. 4 and 5, pixels in some interferometric modulator displays are placed in an actuated or unactuated state by changing the voltage applied to both the rows and columns of the display. As depicted in FIG. 5B, pixels are updated row-by-row by setting each column voltage to either +V_{bias} or -V_{bias} as appropriate and then sending a voltage pulse to the row to be updated. Voltage switching on any given column can occur many times while updating all rows in a given frame. In contrast, voltage switching on each row in a given frame occurs less frequently during a frame update. Accordingly, power dissipation due to capacitive charging of interferometric modulators occurs primarily due to voltage switching on the column leads. Therefore, in one embodiment, power consumption due to voltage pulses to row leads are ignored and power is determined based on the sequential voltage switching between +V_{bias} or −V_{bias} and vice versa on column leads during a frame refresh. In some embodiments, not all pixels need to be refreshed. For example, if certain rows do not contain any pixels that change, voltage pulses to not need to be sent to those rows during the frame refresh and voltage switching on some columns may not be required, thereby reducing the power consumed during the frame.

In general, power consumed by voltage switching on a given column (e.g., the j-th column) may be determined from:

$${P}_{j} = {\sum }_{i = 1}^{{N}_{s}} \frac{1}{2 T} {C}_{ij} {V}_{S}^{2}$$

where i identifies a particular row, j identifies a particular column, N_{S} is the number of voltage switches on the column line during a frame, T is the time period for display of the frame, Cᵢⱼ is the capacitance of the column during the i-th voltage switching, and V_{S} is the magnitude of the voltage switching. The capacitance Cᵢⱼ may be determined from:
Cᵢⱼ=N_{up ij}Cᵤₚ+N_{down ij}C_{down}
where N_{up ij} is the number of pixels in the j-th column that are in the up state during the i-th voltage switching, N_{down ij} is the number of pixels in the down state during the i-th voltage switching, Cᵤₚ is the capacitance of pixels in the up state, and C_{down} is the capacitance of pixels in the down state. Cᵤₚ and C_{down} may be determined by any suitable method, such as the voltage step methods described above or calculated based on the properties of the materials in the pixel. As noted earlier, in some embodiments, Vₛ will be ₂V_{bias} (i.e., the magnitude of voltage switching from +V_{bias} to −V_{bias} or vice versa).

In some embodiments, particularly where the image does not change significantly between frames, the power of a column may be approximated by:

$${P}_{j} = \frac{1}{2 T} {C}_{j} {V}_{S}^{2} {N}_{Sj}$$

where Cⱼ is the capacitance of the j-th column and N_{Sj} is the number of voltage switching events on the j-th column during the frame. In this expression, the capacitance of the j-th column is given by:
Cⱼ=N_{up j}Cᵤₚ+N_{down j}C_{down}
which assumes that the content of the column (i.e., as determined by N_{up j} and N_{down j}) does not change from one switching event to the next.

The power consumed by the entire display during one frame may be determined by summing over all of the columns:

$${P}_{display} = {\sum }_{j = 1}^{{N}_{col}} {P}_{j}$$

where N_{col} is the number of columns in the display.

It will be appreciated that the power consumed by any given column depends significantly on the content of the column (e.g., as determined by N_{up j} and N_{down j}) as well as the content of other parts of the image which affects the number of voltage switches required on the column (e.g., N_{S j}). Accordingly, in one embodiment, a computer-implemented method is provided for estimating power consumed by a display, such as an interferometric modulator display, where the method includes providing an image or a series of images as input and then determining the power consumed during one or more frames by the display. In some embodiments, the algorithms for determining the power models pixels and/or subpixels in the display with capacitors, where pixels and/or subpixels that are on are assigned a different capacitance value than pixels that are off. In some embodiments, the algorithm calculates power consumed be each column in the display. In some embodiments, the algorithm calculates power consumed by each column during each voltage switch on the column. In some embodiments, power is determined while less than the entire image is updated during a frame refresh. In some embodiments, the algorithm includes instructions for reading and processing images or a series of images.

To implement the above described algorithms, a processor or graphics processor may be provided coupled to a computer readable medium that stores instructions for executing the algorithm. The processor may be part of a general purpose computer or be significantly dedicated to executing the algorithms. For example, a processor may be incorporated within a display package for calculating power consumption and then making decisions regarding management of frame refreshes. In some embodiments, different rows are updated at different rates in order to reduce power consumption. In other embodiments, the display resolution can be coarsened to reduce the power by reducing the number of columns that need to be voltage switched. The system and methods described above may be used to estimate the power consumption required for the next image or series of images to be displayed and then decide whether to reduce power consumption by updating only portions of the display or by changing the frequency of updating various rows or the frequency of frame refreshes in general. In some embodiments, the display may be switched to different power consumption modes based on the predicted future power requirements for images displayed on the display and the power available from a power source. Various modes useful for reducing power in interferometric modulator displays are disclosed in co-pending U.S. application Ser. No. 11/097,827, filed on Apr. 1, 2005, which is incorporated herein by reference in its entirety. In one embodiment, the time to drainage of the power source may be displayed to the user based on the power consumption predicted using the above methods and systems.

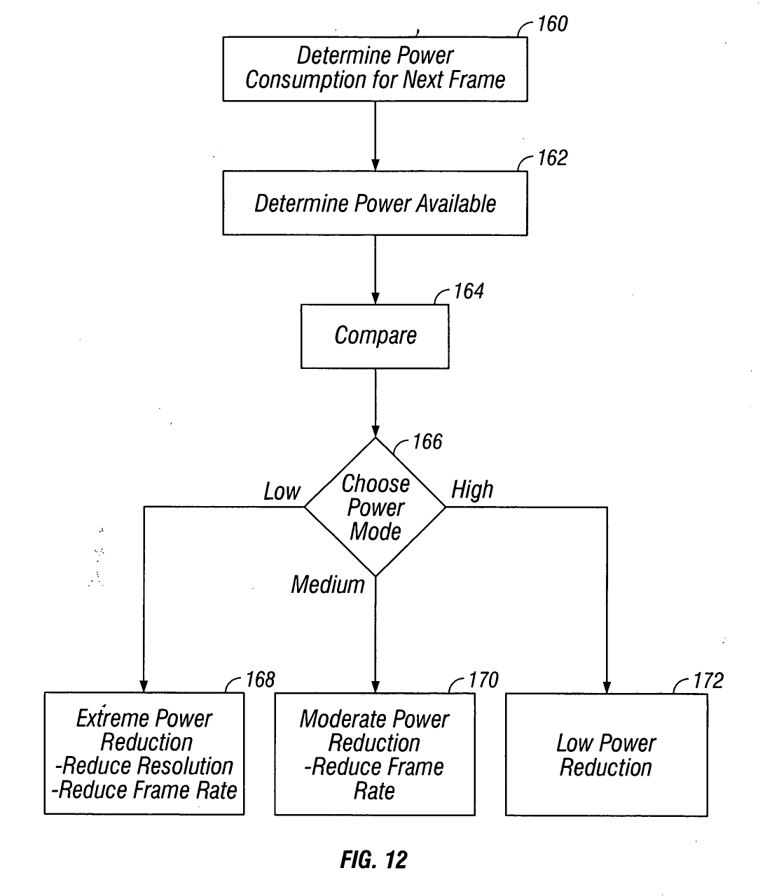

One example of a method for estimating future power consumption and adjusting the power consumption mode accordingly is depicted in FIG. 12. At block 160, the power consumption of one or more future display frames is estimated. Any of the methods described above may be used for estimating the power consumption of a given image in a given display. In one embodiment, the future image may be read from a frame buffer such as the frame buffer 28 depicted in FIG. 6B. At block 162, the future availability of power is determined. This determination may include determining the current state of a power source, such as a battery, to predict power and energy availability. The determination may also include estimating the amount of power needed by other system components. Next, at block 164, the estimated power need is compared to the power available. In one embodiment, the comparison simply involves subtracting the estimated power need from the available power to determine if there is a short fall. Those of skill in the art will appreciate other methods of comparing the power need with availability. Then at block 166, a power mode is chosen based on the comparison in block 164. If it is determined that a low power mode is required, the process may then proceed to block 168 where extreme power reduction methods are taken, such as reducing the resolution of the display and/or reducing the frame rate as described above. If a medium power mode is required, the process may then proceed to block 170 where moderate power reduction methods are taken, such as only reducing the frame rate. Finally, if a high power mode is acceptable, the process may then proceed to block 172 where low or no power reduction methods are taken. Those of skill in the art will appreciate that there are many possible power modes and power reduction methods that may be utilized.

The computer readable medium may be any suitable medium such as magnetic media, optical media, or semiconductor media. In various embodiments, the computer readable media is a disk drive, a compact disk, or RAM. In some embodiments, a user interface is provided that facilitates a user providing images to the algorithm and that can display results of the power calculations to the user. Furthermore, in some embodiments, the user interface enables the user to provide display parameters such as the number of rows in the display, the number of columns in the display, the capacitance of bright and dark state pixels, the voltage scheme employed by the display, the frame rate, etc. In various embodiments, the user interface includes both software and hardware components such as a keyboard, mouse, monitor, printer, and graphical interface. Such embodiments allow a developer to use a computer to predict power consumption needs during development of a display device.

### EXAMPLES

To demonstrate the effect of image content on power consumption, power consumption was predicted for various images displayed on a 160 pixel×160 pixel monochrome interferometric modulator display. The bright state (unactuated) pixels were modeled as capacitors having a capacitance of 0.71 pF. The dark state (actuated) pixels were modeled as capacitors having a capacitance of 10.8 pF. The frame rate used was 1 s per frame. V_{bias} was 5 volts (e.g., the switching voltage on the columns was 10 volts).

### Example 1

### 4×4 Checkerboard Image

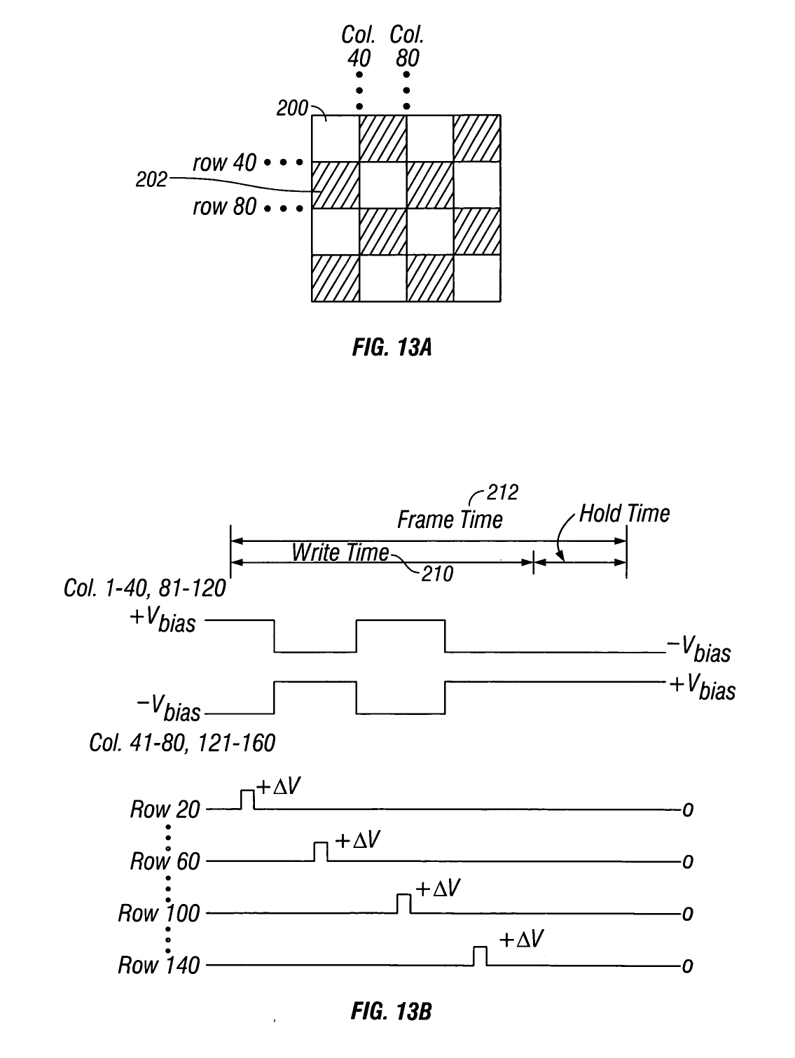

As depicted in FIG. 13A, a 4×4 checkerboard image was modeled where every 40 pixel×40 pixel area was in an opposite state (i.e., bright or dark). For example, all pixels in the square 200 between column 1 and column 40 and between row 1 and row 40 were in a bright state. In contrast, all pixels in the square 202 between column 1 and column 40 and between row 41 and row 80 were in a dark state. The image was assumed to be the same from frame to frame. To maintain the image on the display when all the rows are refreshed in each frame, the voltage driving scheme depicted in FIG. 13B may be used. During the write time 210 portion of the frame time 212, a +ΔV pulse is sequentially applied to each row line in the display. During each pulse, the voltages on each column may be set to either +V_{bias} or −V_{bias} so that the net voltage applied to each pixel results in the pixel voltage being such that the pixel is forced to actuate (e.g., −V_{bias}−ΔV), deactuate (e.g., +V_{bias}−ΔV≈0), or remain in the previous state (e.g., the row voltage is 0 so that the voltage is either +V_{bias} or −V_{bias} within the hysteresis memory window). In order to maintain the pattern depicted in FIG. 13A, columns 1-40 and 81-120 are set to +V_{bias} and columns 41-80 and 121-160 are set to −V_{bias} while rows 1-40 and 81-120 are pulsed, and columns 1-40 and 81-120 are set to −V_{bias} and columns 41-80 and 121-160 are set to +V_{bias} while rows 41-80 and 121-160 are pulsed. As depicted in FIG. 13B, each column line undergoes three voltage transitions of amplitude 2 V_{bias} during each frame.

As can be seen in FIG. 13A, each column has half of its pixels in an actuated state and half in an unactuated state. Accordingly, the capacitance of each column is the same and was calculated to be C=80 pixels×0.71 pF+80 pixels×10.8 pF=921 pF. As noted above, the number of voltage switches for each column is three (i.e., N_{S}=3) and the amplitude of the voltage switching was 10 V. Accordingly, using the formulas described above, the power consumed during one frame was calculated to be 22.1 μW.

### Example 2

### 16×16 Checker Board Image

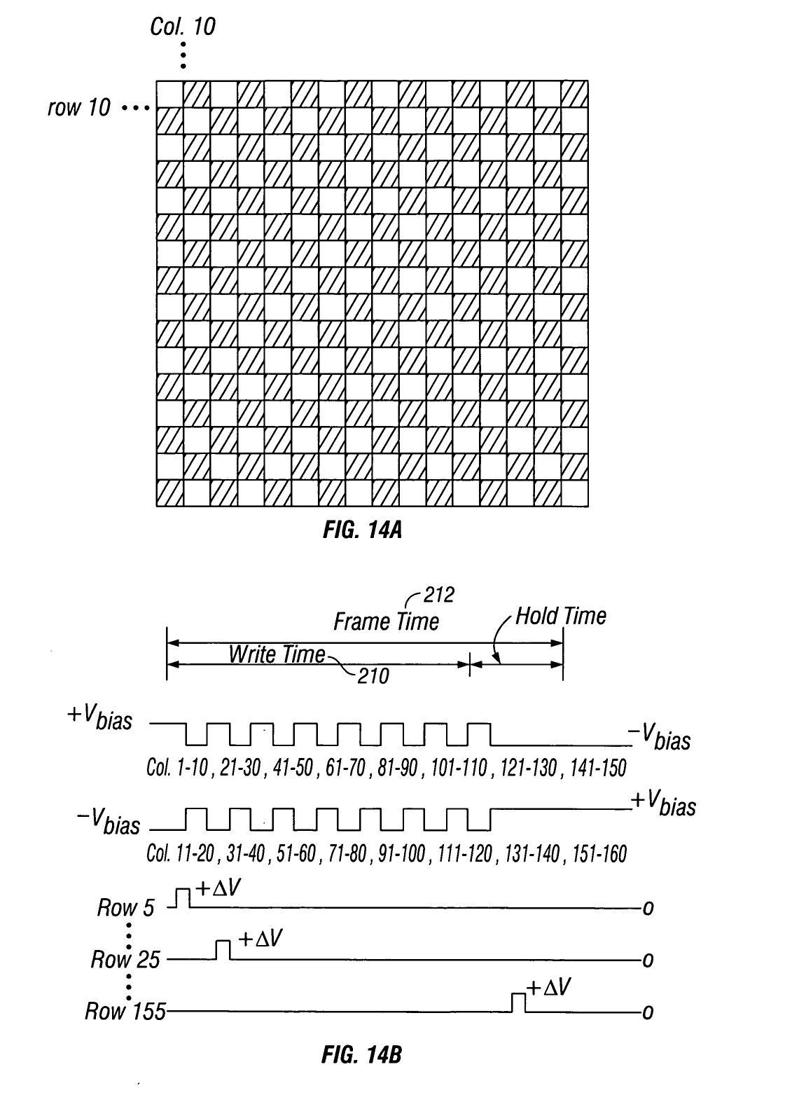

As depicted in FIG. 14A, a 16×16 checkerboard image was modeled where every 10 pixel×10 pixel area was in an opposite state (i.e., bright or dark). The image was assumed to be the same from frame to frame. To maintain the image on the display when all the rows are refreshed in each frame, the voltage driving scheme depicted in FIG. 14B may be used. During the write time 210 portion of the frame time 212, a +ΔV pulse is sequentially applied to each row line in the display. During each pulse, the voltages on each column are set to either +V_{bias} or −V_{bias} so that the net voltage applied to each pixel results in the pixel voltage being such that the pixel is forced to actuate (e.g., +V_{bias}−ΔV), deactuate (e.g., −V_{bias}−ΔV≈0), or remain in the previous state (e.g., the row voltage is 0 so that the voltage is either +V_{bias} or −V_{bias} within the hysteresis memory window). In order to maintain the pattern depicted in FIG. 14A, the column voltages are switched 15 times during the write time 210 with columns 1-10, 21-30, 41-50, 61-70, 81-90, 101-110, 121-130, 141-150, and 161-170 having polarity opposite to columns 11-20, 31-40, 51-60, 71-80, 91-100, 111-120, 131-140, and 151-160 at any given time. As depicted in FIG. 14B, each column line undergoes 15 voltage transitions of amplitude 2 V_{bias} during each frame.

As can be seen in FIG. 14A, each column has half of its pixels in an actuated state and half in an unactuated state. Accordingly, the capacitance of each column is the same as calculated in Example 1 (C=80 pixels×0.71 pF+80 pixels×10.8 pF=921 pF). As noted above, the number of voltage switches for each column is 15 (i.e., N_{S}=15) and the amplitude of the voltage switching was 10 V. Accordingly, using the formulas described above, the power consumed during one frame was calculated to be 110.5 μW. This result demonstrates that the power consumed during a frame depends significantly on image content. For example, although the capacitance of each column is the same in Examples 1 and 2 (i.e., there are the same number of bright and dark pixels), the power consumed is an order of magnitude different.

### Example 3

### Partial Frame Update

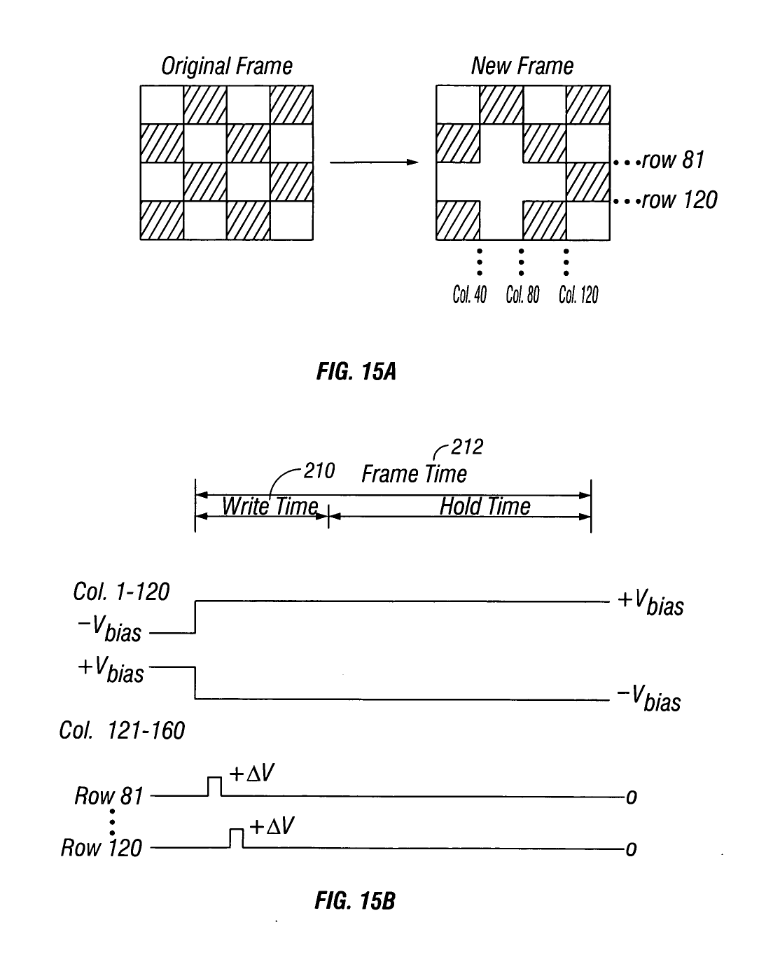

The updating of a 4×4 checkerboard image as an Example 1 to the new image depicted in FIG. 15A was modeled. The difference in the new frame was that the pixels in the square defined by columns 81 to 120 and rows 41 to 80 were changed from a dark state (actuated) to a bright state (unactuated). Rather than refreshing the entire image by sending voltage pulses to all row lines, pulses were sequentially sent to only those rows containing pixels that changed (i.e., rows 8 to 120). Because pulses are applied to only 40 rows during the frame time 212, the write time 210 is shorter than when the entire display is refreshed. The column voltages required to generate the new frame from the original frame are depicted in FIG. 15B. All columns required one voltage transition. The polarity of columns 1 to 120 was opposite to that of columns 121-160.

The capacitance of columns 1-40 and 81-160 is the same as that for the columns in Examples 1 and 2 (C=80 pixels×0.71 pF+80 pixels×10.8 pF=921 pF). In contrast, the capacitance for columns 41-80 is determined by C=120 pixels×0.71 pF+40 pixels+10.8 pF=517.2 pF (i.e., 120 pixels in a bright state (unactuated) and 40 pixels in a dark state (actuated)). As noted above, the number of voltage switches for each column was one (i.e., N_{S}=1) and the amplitude of the voltage switching was 10 V. Accordingly, using the formulas described above, the power consumed during one frame with the indicated partial updating was calculated to be 6.6 μW, which is significantly less than the 22.1 μW for a total frame refresh calculated in Example 1. Accordingly, modeling can be used to determine power savings for partial display refresh during certain image content transitions.

Although the invention has been described with reference to embodiments and examples, it should be understood that numerous and various modifications can be made without departing from the spirit of the invention. Accordingly, the invention is limited only by the following claims.

What is claimed is:

1. A method of estimating power consumption by a display, comprising:
measuring capacitance of one or more pixels in the display; and
determining power consumed by the one or more pixels based on the measured capacitance.

2. The method of claim 1, wherein capacitance of a single pixel is measured.

3. The method of claim 1, wherein capacitance of a row or column of pixels is measured.

4. The method of claim 1, wherein capacitance of all pixels in the display is measured.

5. The method of claim 1, wherein said measuring comprises applying a voltage pulse across the one or more pixels and measuring resulting current.

6. The method of claim 5, wherein a relaxation time is determined from said measuring of current.

7. The method of claim 1, wherein the pixels have different capacitance states depending on whether the pixels are on or off and capacitance of pixels in a high-capacitance state is measured separately from capacitance of pixels in a low-capacitance state.

8. The method of claim 7, wherein the display includes interferometric modulators.

9. The method of claim 1, wherein capacitance of different color subpixels are measured separately from each other.

10. A method of estimating power consumption by a display, comprising:
determining power consumed by pixels in the display that are on; and
separately determining power consumed by pixels in the display that are off.

11. The method of claim 10, wherein power consumed by a single on pixel and a single off pixel is determined.

12. The method of claim 10, wherein power consumed by a row or column of on pixels and a row or column of off pixels is determined.

13. The method of claim 10, wherein power consumed by the display when all pixels are on and power consumed by the display when all pixels are off is determined.

14. The method of claim 10, wherein determining power comprises:
applying a voltage step to one or more pixels; and
measuring resulting current.

15. The method of claim 10, wherein said determining steps include:
modeling pixels by a capacitor; and
determining power consumed by the capacitor.

16. The method of claim 10, wherein power consumed by different color subpixels are determined separately from each other.

17. The method of claim 10, wherein the display includes interferometric modulators.

18. A method of estimating power consumption by a display comprising a plurality of interferometric modulators, the method comprising:
determining if one or more of the interferometric modulators are in an actuated state or an unactuated state;
applying a voltage stimulus to the one or more interferometric modulators; and
measuring current to or from the one or more interferometric modulators that results from the voltage stimulus.

19. The method of claim 18, wherein said determining includes applying a voltage or series of voltages to the one or more interferometric modulators that are known to place the one or more interferometric modulators in an actuated or unactuated state.

20. The method of claim 18, wherein said determining includes visually observing whether the one or more interferometric modulators are in a bright or dark state.

21. The method of claim 18, wherein said determining includes detecting light reflected from the one or more interferometric modulators with a photodetector or spectrometer.

22. The method of claim 18, wherein said determining includes determining a color of the one or more interferometric modulators.

23. The method of claim 18, wherein the one or more interferometric modulators is a row or column of interferometric modulators.

24. The method of claim 18, wherein the one or more interferometric modulators includes all interferometric modulators in the display.

25. The method of claim 18, further comprising determining a capacitance value of a capacitor that would produce a current substantially similar to the measured current if the voltage pulse were applied to the capacitor.

26. A computer-implemented method of modeling power consumed by a display depicting an image, comprising:
providing the image as input; and
determining power consumed by the display while the image is displayed by modeling each pixel with a capacitor, wherein pixels that are off are assigned a different capacitance than pixels that are on.

27. The method of claim 26, wherein determining power includes determining power consumed by each column of the image.

28. The method of claim 26, wherein pixels that are on have a different capacitance than pixels that are off and determining the power includes determining how many pixels in each column of the image are in the higher capacitance state.

29. The method of claim 26, wherein determining the power includes determining power consumed by the display while the image is displayed for a single frame.

30. The method of claim 29, wherein determining the power includes determining power consumed by the display during a frame refresh where less than the entire image is updated.

31. The method of claim 26, wherein determining the power includes determining power consumed by each column of the image during each change of voltage applied to the column.

32. The method of claim 26, wherein different color subpixels are assigned different capacitances.

33. The method of claim 26, wherein the display includes interferometric modulators.

34. A system for modeling power consumed by a display depicting an image, comprising:
a processor; and
a computer readable medium coupled to the processor and comprising instructions for modeling power consumed by a display by modeling pixels in the display with capacitors, wherein pixels that are off are assigned a different capacitance than pixels that are on.

35. The system of claim 34, wherein the computer readable medium also includes instructions for reading an input image and determining power consumed by the display when the display displays the image.

36. The system of claim 35, further comprising a user interface adapted to output the determined power.

37. The system of claim 35, further comprising a user interface adapted to receive input from a user regarding an area of the image for which power is to be determined.

38. The system of claim 34, further comprising a user interface adapted to receive input from a user regarding one or more display parameters selected from the group consisting of the number of rows in the display, the number of columns in the display, the capacitance of pixels that are on, the capacitance of pixels that are off, a voltage or series of voltages applied to the display, and the display refresh rate.

39. The system of claim 34, further comprising the display, wherein the display is in electrical communication with the processor.

40. The display system as recited in claim 39, further comprising:
a first controller configured to send at least one signal to said display; and
a second controller configured to send at least a portion of image data to said first controller.

41. The display system as recited in claim 39, further comprising an image source module configured to send image data to said processor.

42. The display system as recited in claim 41, wherein said image source module comprises at least one of a receiver, transceiver, and transmitter.

43. The display system as recited in claim 39, further comprising an input device configured to receive input data and to communicate said input data to said processor.

44. A system for estimating power consumption by a display, comprising:
means for measuring a capacitance of at least one pixel in the display; and
means for predicting power consumed by the display when an image is displayed using said capacitance.

45. The system of claim 44, wherein said means for measuring includes a voltage source adapted to apply a voltage stimulus to the at least one pixel and a current measuring circuit adapted to measure current resulting from application of said stimulus.

46. The system of claim 44, wherein said means for predicting includes a processor and a computer readable medium coupled to said processor.

47. The system of claim 46, wherein the computer readable medium comprises instructions for modeling power consumed by a capacitor.

48. A display manufactured by a process comprising:
forming a plurality of interferometric modulators on a substrate;
forming electrical connections to said interferometric modulators; and
connecting one or more of said electrical connections to a current sense circuit.

49. The display of claim 48, further comprising a driver controller, wherein the driver controller comprises the current sense circuit.

50. A system for measuring power consumed by a display, comprising:
an image driver adapted to drive pixels in the display such that a series of images are displayed by the display;
a timer adapted to control the amount of time that each image in said series of images is displayed;
a voltage sense circuit adapted to measure the voltages applied to the display during display of each image;
a current sense circuit adapted to measure the current flowing to or from the display during display of each image; and
a power computation module adapted to determine the power consumed by the display while each image is displayed.

51. The system of claim 50, wherein the timer is adapted to vary the amount of time that each image of said series of images is displayed.

52. The system of claim 50, wherein the voltage sense circuit and current sense circuit are incorporated within the image driver.

53. The system of claim 50, wherein the voltage sense circuit and current sense circuit are adapted to measure voltages and currents applied to each column or row of the display separately.

54. The system of claim 50, wherein the power computation module is adapted to determine an instantaneous power consumed by the display.

55. The system of claim 50, wherein the power computation module is adapted to determine power consumed during each frame of each image displayed by the display.

56. The system of claim 50, wherein the power computation module is adapted to determine average power consumed by the display during display of each image.

57. A method for measuring power consumed by a display, comprising:
displaying a series of images on the display; and
determining power consumed by the display during display of the series of images.

58. The method of claim 57, wherein instantaneous power is determined.

59. The method of claim 57, wherein power consumed by each frame displayed on the display is determined.

60. The method of claim 57, wherein average power consumed by display of each image is determined.

61. The method of claim 57, wherein determining the power comprises measuring current applied to the display and computing power from the current.

62. A display identified as usable for a particular purpose by measuring power consumption in the display according to the method of claim 57.

63. A computer-readable medium storing instructions that when executed perform the method comprising:
reading an image; and
determining power consumed by a display while the image is displayed on the display by modeling each pixel in the display with a capacitor, wherein pixels that are off are assigned a different capacitance than pixels that are on.
